(19) United States
(12) Patent Application Publication
(10) Pub. No.: US 2025/0264524 A1
(43) Pub. Date: Aug. 21, 2025

(54) SEMICONDUCTOR ARRANGEMENT

(71) Applicant: Infineon Technologies AG, Neubiberg (DE)

(72) Inventors: Jens Barrenscheen, München (DE); Wei Wang, München (DE)

(21) Appl. No.: 19/054,997

(22) Filed: Feb. 17, 2025

(30) Foreign Application Priority Data
Feb. 21, 2024 (DE) 10 2024 201 587.3

(51) Int. Cl. G01R 31/28

(52) U.S. Cl. CPC G01R 31/2879

(57) ABSTRACT

A mechanism for predicting the occurrence of a fault at a terminal of a semiconductor arrangement is provided. A measure of delay is obtained for each of a plurality of terminals of the semiconductor arrangement. The measures of delay are compared to one another to predict whether or not there is a fault at a terminal of the semiconductor arrangement.

### REFERENCE TO RELATED APPLICATION

This application claims priority to German Application number 10 2024 201 587.3, filed on Feb. 21, 2024, the contents of which are hereby incorporated by reference in their entirety.

### FIELD

The present disclosure relates to the field of semiconductor arrangements, and in particular, to fault detection in a semiconductor arrangement.

### BACKGROUND

There is an increasing use and reliance upon semiconductor arrangements within a wide variety of industries, such as the automotive industry or the manufacturing industry. There is a demand for accurate and timely error or fault detection in such semiconductor arrangements. This demand is particularly important where the failure of a semiconductor arrangement can impact the safety of an operator or individual, such as semiconductor arrangements for motor control in an automotive vehicle.

One area at which a fault may occur in a semiconductor arrangement is at the (input/output) terminals, also known as pins, of the semiconductor arrangement. A terminal is commonly used to transmit information from one semiconductor arrangement to another in a system. The occurrence of a fault or failure at a terminal can lead to incorrect or erroneous signals being transmitted to other devices controlled by the semiconductor arrangement and, ultimately, failure or inappropriate operation of the system in which the semiconductor arrangement is located.

There is therefore a demand for more accurate and/or reliable mechanisms for detecting faults at a terminal of a semiconductor arrangement.

### SUMMARY

There is provided a semiconductor arrangement comprising: a plurality of terminals; one or more signal generators configured to provide a signal to each of the plurality of terminals; and a monitoring system.

The monitoring system is configured to: for each of the plurality of terminals, obtain a respective measure of delay for the signal provided to the respective terminal by the one or more signal generators; and compare the measures of delay to one another to generate an indicator of whether or not a fault has occurred within the plurality of terminals.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a portion of a semiconductor arrangement;

FIG. 2 illustrates waveforms in the semiconductor arrangement;

FIG. 3 illustrates another waveform in the semiconductor arrangement;

FIG. 4 illustrates a method performed by a monitoring system of a proposed semiconductor arrangement;

FIG. 5 illustrates an example approach for performing an act of the method;

FIG. 6 illustrates an example approach for performing a measure determination procedure;

FIG. 7 illustrates further waveforms of the semiconductor arrangement.

### DETAILED DESCRIPTION

The examples described herein provide a mechanism for predicting or detecting the occurrence of a fault at a terminal of a semiconductor arrangement. A measure of delay is obtained for each of a plurality of terminals of the semiconductor arrangement. The measures of delay are compared to one another to predict or detect whether or not there is a fault at a terminal of the semiconductor arrangement.

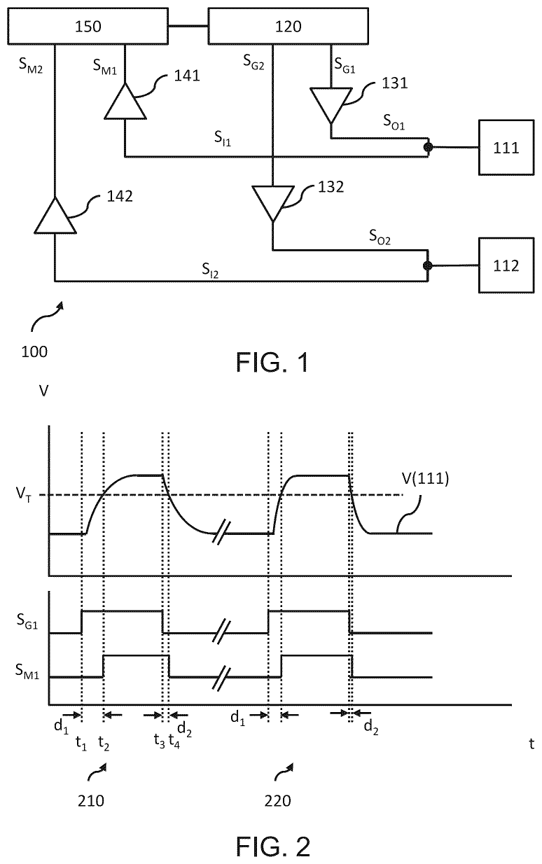

FIG. 1 illustrates a portion of a semiconductor arrangement 100 in which embodiments may be employed, for the sake of improved contextual understanding. It will be appreciated that the semiconductor arrangement 100 may comprise other components and/or elements that are not detailed, illustrated or described in this disclosure for the sake of conciseness. The semiconductor arrangement may, for instance, be an integrated circuit or semiconductor chip that includes devices (e.g., transistors) disposed on one or more silicon substrate(s), wherein the devices are connected through by back end of line (BEOL) metallization/interconnect structures including metal lines that are stacked over one another and connected to one another through vias that vertically connect the various metal lines. The silicon substrates can for example, be bulk monocrystalline silicon substrates, or can be silicon on insulator (SOI) substrates, among others.

In the context of the present disclosure, a semiconductor arrangement is any semiconductor device or arrangement of semiconductor devices positioned on one or more dies or substrates. For instance, the semiconductor arrangement may comprise a single semiconductor chip implemented as a single die, or multiple semiconductor dies either integrated in a single package or in multiple separate packages electrically connected to each other.

The semiconductor arrangement 100 comprises a plurality of terminals 111, 112 and one or more signal generators 120. The signal generator(s) 120 is/are coupled to the plurality of terminals. The signal generator(s) is/are configured to generate and provide a (generated) signal S_{G1}, S_{G2} to each of the plurality of terminals. Each terminal may, in practice, be a pin of the semiconductor arrangement, e.g., an exposed location at which an external device is able to connect and/or communicate with the semiconductor arrangement. In this way, at least one of the terminals may be connected to a receiver circuit or similar.

An example of a suitable signal generator is a microprocessing system configured to generate one or more signals for outputting from the semiconductor arrangement. Other examples of signal generators are widely known in the art, including FPGAs and ASICs.

In practice, the semiconductor arrangement 100 may also comprise a respective output driver 131, 132 for each terminal 111, 112. Each output driver 131, 132 is connected between the signal generator(s) 120 and a different, respective terminal 111, 112. Each output driver 131, 132 receives a respective generated signal S_{G1}, S_{G2} from the signal generator(s) 120 and provides an output signal S_{O1}, S_{O2} to its respective terminal 111, 112.

Each output driver 131, 132 may, for instance, function to amplify the received generated signal S_{G1}, S_{G2} for outputting from the semiconductor arrangement. In this way, each output signal S_{O1}, S_{O2} may effectively be an amplified version of a respective generated signal S_{G1}, S_{G2}.

The semiconductor arrangement 100 may also comprise a respective input driver 141, 142 for each terminal. Each input driver 141, 142 is connected to a different, respective terminal 111, 112. Each input driver 141, 142 receives or reads a respective input signal S_{I1}, S_{I2} from its respective terminal and provides a respective monitoring signal S_{M1}, S_{M2} responsive thereto. Each input driver 141, 142 may, for instance, function to amplify the read input signal S_{I1}, S_{I2} to produce the respective monitoring signal S_{M1}, S_{M2}.

It will be appreciated that the input signals S_{I1}, S_{I2} and monitoring signals S_{M1}, S_{M2} will be responsive to both a signal provided to the terminal(s) by an external device or source (if connected) as well as the output signal S_{O1}, S_{O2} provided using the signal generator(s) 120.

The present disclosure recognizes that each terminal, or wiring connected thereto, is at risk of a fault. More particularly, it has been recognized that a measure of delay for a generated signal S_{G1}, S_{G2} is influenced or affected by the occurrence of a fault at a terminal. A fault at a terminal may be due to a circuit in the semiconductor arrangement (e.g., a fault in the output driver or a missing power supply) or outside the semiconductor arrangement (e.g., a bad electric connectivity to the terminal, or a short circuit to another signal line or another terminal). Thus, faults can be broadly considered as being either internal or external (to the semiconductor arrangement).

For instance, it has been identified that the occurrence of a fault at a terminal will result in a change or variation in the delay between a change in a generated signal S_{G1}, S_{G2} and a corresponding change in an output signal Sot, S_{O2}, input signal S_{I1}, S_{I2} or monitoring signal S_{M1}, S_{M2} that is responsive to the (change in the) generated signal.

Thus, for instance, if the generated signal S_{G1}, S_{G2} pulses (e.g., low-high-low), then there will be a delay before a corresponding pulse occurs in the output signal S_{O1}, S_{O2} and any signal derived therefrom (i.e., the input signal S_{I1}, S_{I2} or monitoring signal S_{M1}, S_{M2}). In particular, there will be a delay between the pulse in the generated signal S_{G1}, S_{G2} beginning (e.g., rising from low to high) and a corresponding beginning of the pulse in the output signal S_{O1}, S_{O2} and any signal derived therefrom (i.e., the input signal S_{I1}, S_{I2} or monitoring signal S_{M1}, S_{M2}). Similarly, there will be a delay between the pulse in the generated signal S_{G1}, S_{G2} ending (e.g., falling from high to low) and a corresponding ending of the pulse in the output signal S_{O1}, S_{O2} and any signal derived therefrom (i.e., the input signal S_{I1}, S_{I2} or monitoring signal S_{M1}, S_{M2}).

As another example, a change in the time taken for a voltage at a terminal to reach a voltage defined by the generated signal is also influenced by the occurrence of a fault at that terminal or its associated wiring. In other words, the slew-rate at a terminal is influenced by the occurrence of a fault at that terminal or its associated wiring.

It is proposed to make use of measures of delay for each terminal (or generated signal) to generate an indicator of whether or not a fault has occurred within the plurality of terminals. In particular, the measures of delay for different terminals are compared to one another to generate an indicator of whether or not a fault has occurred within the terminals.

Any individual measurement of a delay may change from one measurement to another measurement due to various effects, such as temperature or supply voltage dependencies. Measurements of a delay from the same location in two (different) semiconductor arrangements of the same type may also show a significant variation, e.g., due to process variation during the fabrication of the devices, commonly modelled or monitored using a process corner technique. As a consequence, the results of the same measurement may show a certain spread, even if there is no failure or fault present. This makes it difficult to determine an absolute threshold for pass/fail. Comparing the results of different measures of delay within the same semiconductor arrangement reduces the spread, because the results would change in the same way and keep their relation, e.g., if the temperature or the supply voltage changes.

In particular, this recognition is exploited to define a monitoring system 150 of the semiconductor arrangement 100 that compares measures of delay for different terminals to determine or decide whether or not a fault has occurred. The monitoring system 150 is coupled to at least the plurality of terminals.

In general, it can be assumed that if no fault has occurred, then the differences between the measures of delay will be substantially the same (e.g., or change only gradually) throughout a session in which the semiconductor arrangement is active and/or a lifetime of the semiconductor arrangement. If there is a sudden change or deviation in the differences between the measures of delay, then it can be assumed that a fault has occurred.

FIG. 2 illustrates the effect of a fault on a delay between a change in a generated signal S_{G1} (provided to an output driver) and a corresponding change in the monitoring signal S_{M1} for a same terminal. The skilled person will appreciate that the output signal and the input signal will have a similar response to the monitoring signal (albeit, with a smaller delay).

In particular, FIG. 2 illustrates a respective example waveform for a generated signal S_{G1} and a monitoring signal S_{M1} for a first terminal during a first period of time 210 (before a fault occurs at the first terminal) and a second period of time 220 (after a fault occurs at the first terminal). For the sake of completeness and contextual understanding, a voltage V(111) at the first terminal is also illustrated.

In this scenario, the generating signal S_{G1} is configured to switch between a first low voltage and a first high voltage. More specifically, the generating signal S_{G1} undergoes a series of pulses, e.g., for performing pulse width modulation, digital/binary communications and so on. The voltage V(111) at the first terminal follows the generating signal, although it requires a non-zero amount of time to ramp or rise to the first high voltage and ramp or fall to the first low voltage.

In this scenario, the monitoring voltage S_{M1} is configured to indicate whether or not the voltage V(111), read from the first terminal, exceeds a threshold voltage V_{T}. In particular, the monitoring voltage S_{M1} rises to a first high voltage when the voltage V(111) exceeds the threshold voltage V_{T} and falls to a first low voltage when the voltage V(111) does not exceed the threshold voltage V_{T}.

A measure of delay may be responsive to at least one time delay between a change in the generated signal S_{M1} (e.g., a rising edge or a falling edge) provided to the output driver connected to the respective terminal; and a corresponding change (e.g., a corresponding rising edge or a falling edge) in the output signal, or a signal generated from the output signal such as the monitoring signal S_{M1}, read from the respective terminal, that is responsive to the change in the generated signal.

One example measure of delay is a time delay d₁ (e.g., measured in a unit of time such as microseconds or nanoseconds) between a first point in time t₁ and a second point in time t₂. The first point in time t₁ is a time at which a voltage of the generated signal S_{G1} changes from a first low voltage to a first predetermined percentage of a first high voltage. The second point in time t₂ is a time at which the voltage of the output signal, or the signal generated from the output signal (such as the monitored voltage S_{M1}), changes from a second low voltage to a second predetermined percentage of a second high voltage.

This provides an example of a measure of delay in which the change in the generated signal is a rising edge of the generated signal and the corresponding change in the output signal, or the signal generated from the output signal, is a corresponding rising edge of the output signal or the signal generated from the output signal. This type of measure of delay can be labelled a rising edge delay.

The first point in time t1 may be detected using a first Schmitt trigger and the second point in time t2 may be detected using a second Schmitt trigger. Accordingly, the monitoring system may comprise a first Schmitt trigger and a second Schmitt trigger.

Alternatively, the first point in time t1 may be detected by the signal generator directly providing a version of the generated signal to the monitoring system (e.g., digitally). In this way, only a single Schmitt trigger needs to be used, e.g., for monitoring the voltage of the output signal (or a signal generated therefrom).

Another example measure of a delay is a second time delay d₂ is a falling edge of the generated signal and the corresponding change in the output signal, or the signal generated from the output signal, is a corresponding falling edge of the output signal or the signal generated from the output signal. This type of measure of delay can be labelled a falling edge delay.

For instance, the second time delay may be a time delay d₂ (e.g., measured in a unit of time such as microseconds or nanoseconds) between a third point in time t₃ and a fourth point in time t₄. The third point in time t₃ is a time at which a voltage of the generated signal S_{G1} changes from a first high voltage to a first predetermined percentage of the first high voltage. The fourth point in time t₄ is a time at which the voltage of the output signal, or the signal generated from the output signal (such as the monitored voltage S_{M1}), changes from a second high voltage to a second predetermined percentage of the second high voltage.

The third point in time t₃ may be detected using a first Schmitt trigger and the fourth point in time t₄ may be detected using a second Schmitt trigger. Accordingly, the monitoring system may comprise a first Schmitt trigger and a second Schmitt trigger. If both the rising edge delay and the falling edge delay are monitored or determined, then the same (first) Schmitt trigger may be used to detect the first and fourth points in time, and the same (second) Schmitt trigger may be used to detect the second and third points in time.

Alternatively, the third point in time t3 may be detected by the signal generator directly providing a version of the generated signal to the monitoring system (e.g., digitally). In this way, only a single Schmitt trigger needs to be used, e.g., for monitoring the voltage of the output signal (or a signal generated therefrom).

Previously described approaches for generating a measure of delay for a terminal make use of two signals, e.g., a generated signal to be provided to a terminal and a further signal that changes (with a delay) responsive to the generated signal—such as a signal read from the terminal (e.g., the input signal or the monitoring signal). In this way, the measure of delay represents the delay between a first signal (generated signal) changing and a second signal (e.g., output, input or monitoring) changing responsive to the change in the first signal.

However, another approach for generating a measure of delay for a terminal makes use of only a single signal read from the terminal, which signal is known as a terminal signal. The previously described input signal and monitoring signal are examples of the terminal signal.

In this approach, the measure of delay is responsive to a transition time of the terminal signal read from the terminal. A transition time is a length of time taken for a voltage of the terminal signal to rise from a first value to a second value or fall from a third value to a fourth value. This approach recognizes that a change in the time taken for a voltage at the terminal node to change (i.e., a change in the slew rate at the terminal node) is responsive or indicative of a fault at the terminal (and/or connecting circuitry).

Thus, rather than processing the generated signal and a signal derived from the output signal (e.g., the monitored signal), it is possible to generate a measure of delay from a terminal signal (being a signal read from the terminal) alone.

One approach for detecting a time at which the voltage of a terminal signal crosses a value is to make use of a respective diode (e.g., having a fixed or known breakdown voltage) or comparator circuit.

In particular, a first Schmitt trigger may be used to detect when the terminal signal crosses the first value and a second, different Schmitt trigger (with different switching thresholds) may be used to detect when the terminal signal crosses the second value.

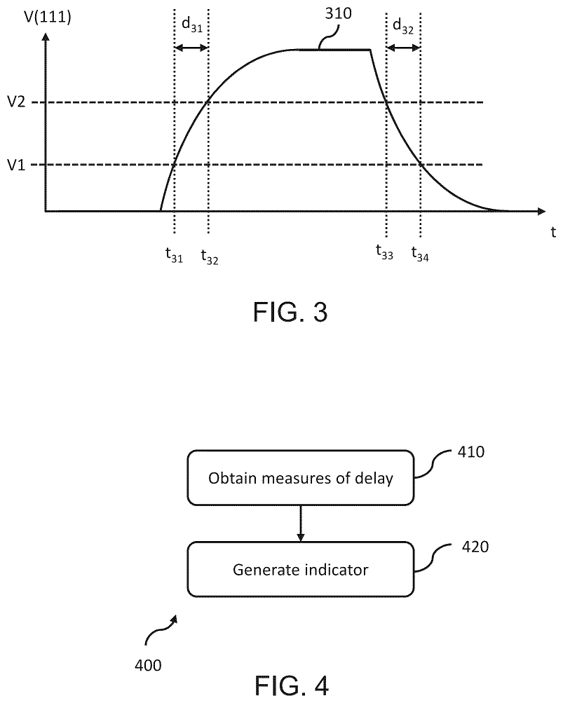

FIG. 3 illustrates two examples of a transition time d₃₁, d₃₂. The measure of delay may be proportional or equal to the transition time. In particular, FIG. 3 illustrates a representative waveform 310 of a voltage V(111) at a terminal, which is read by a terminal signal (e.g., the input signal or the monitoring signal).

In particular, a first transition time d₃₁ is a length of time taken for a voltage V(111) of the terminal signal to rise from a first value V1 to a second value V2, such that the second value is greater than the first value. Thus, the first transition time is a length of time between a first transition time point t31, when the voltage of the terminal signal reaches the first value V1, and a second transition time point t32, when the voltage of the terminal signal subsequently reaches the second value V2. As previously explained, this length of time can be determined by monitoring the terminal signal. The first transition time may be labelled a rising edge transition time.

A second transition time d₃₂ is a length of time taken for a voltage V(111) of the terminal signal to fall from a third value V2 to a fourth value V1, such that the fourth value is less than the third value. Thus, the second transition time is a length of time between a third transition time point t₃₃, when the voltage of the terminal signal reaches the third value V2, and a fourth transition time point t₃₄, when the voltage of the terminal signal subsequently reaches the fourth value V1. The second transition time may be labelled a falling edge transition time.

The measured values strongly depend on the driving capability of the output driver (in most cases, the driving capability towards a lower signal level is stronger than the one towards a higher signal level), the power supply value of the driver and the location of the (Schmitt trigger) thresholds with respect to the power supply value. In this illustrated example, the first and third values are the same (but this is not essential) and the second and fourth values are the same (which is also not essential). It is also not essential to monitor both the first and second transition times, rather only one should be detected or determined.

It is possible to use two Schmitt triggers (e.g., with different sets of switching thresholds) to produce a rising edge transition time and a falling edge transition time, due to the hysteric effect of a Schmitt trigger. In this approach, each Schmitt trigger my monitor the terminal signal. The rising edge transition time may be a difference between a time at which a first Schmitt trigger changes from a first output to a second output and a time at which a second Schmitt trigger changes from a third output to a fourth output. The falling edge transition time may be a difference between a time at which the first Schmitt trigger reverts from the second output to the first output and a time at which the second Schmitt trigger reverts from the fourth output to the third output.

Thus, the monitoring system may comprise and use two Schmitt triggers for determining the rising edge transition time and/or the falling edge transition time, to determine a respective measure of delay.

It will be appreciated that each measure of delay, such as those illustrated and described with reference to FIGS. 2 and 3, changes when an error or fault occurs at the terminal, or in its associated wiring.

However, the present disclosure further recognizes that this measure of delay is influenced by other factors, such as a change in temperature and/or supply voltage for the signal generator and/or semiconductor arrangement.

It is herein proposed to compare the measures of delay for a plurality of terminals to one another to generate the indicator of whether or not a fault has occurred within the plurality of terminals. This approach recognizes that the conditions of temperature and supply voltage will remain substantially the same between different terminals. Accordingly, changes or movement in the difference between measures of delay may indicate that a fault has occurred with a greater degree of accuracy, and reducing a likelihood of misidentifying a fault that is, in practice, attributable to a temperature or supply voltage variation.

Thus, with reference to FIG. 1, there is provided a monitoring system configured to generate an indicator of whether or not a fault has occurred. The monitoring system compares the measures of delay for a plurality of terminals to produce the indicator.

It will be appreciated that the monitoring system may comprise processing circuitry (e.g., a microprocessor, an FPGA, an ASIC) to generate the indicator, and preferably comprises digital processing circuitry.

FIG. 4 is a flowchart illustrating a method 400 performed using the monitoring system to generate an indicator of whether or not a fault has occurred.

The method 400 comprises an act 410 of, for each of the plurality of terminals, obtaining a respective measure of delay for the signal provided to the respective terminal by the one or more signal generators. Examples of measures of delay have been previously disclosed, with further approaches later described.

The method 400 also comprises an act 420 of comparing the measures of delay to one another to generate an indicator of whether or not a fault has occurred within the plurality of terminals.

As a simple example, act 420 may comprise determining a difference between each measure of delay and each other measure of delay. Thus, the number m of differences determined will be equal to:

$$m = \frac{n !}{2 ! ( n - 2 ) !} \qquad ( 1 )$$

where n is the number of measures of delay obtained (i.e., the number of terminals).

In this simple example, act 420 may comprise controlling the indicator to predict that a fault has occurred responsive to any determined difference breaching a predetermined threshold. Otherwise, the act 420 may comprise controlling the indicator to predict that no fault has occurred.

As another simple example, act 420 may comprise determining, for each measure of delay, a ratio between the measure of delay and each other measure of delay. The same number of measures as set out in equation (1) may be generated, or twice this number (e.g., if also determining an inverse of the ratio for each pair of measures of delay). Act 420 may correspondingly comprise controlling the indicator to predict that a fault has occurred responsive to any determined ratio breaching a predetermined threshold ratio. Otherwise, the act 420 may comprise controlling the indicator to predict that no fault has occurred.

The number of pairs of measures may be scaled depending on the need of information. If a simple go/nogo test is intended (e.g., to check for failures that have already occurred), the number of pairs of measures to be considered can be quite low. If, as a second use case, a prediction of a future fail is intended, a higher number of pairs may lead to a better prediction, because more changes or failure scenarios may be observed. This second use case may also be covered by using the measured value as input to an AI algorithm.

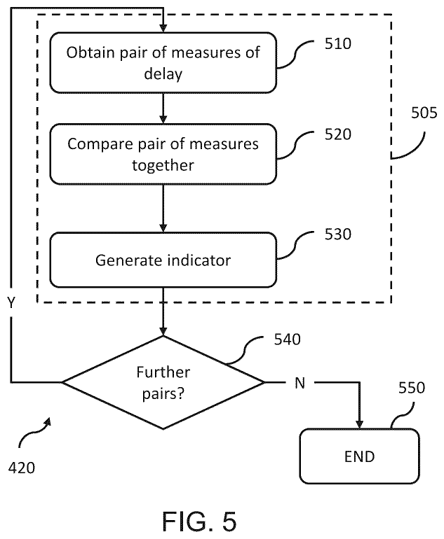

FIG. 5 illustrates another approach for performing act 420 of comparing the measures of delay to one another to generate an indicator of whether or not a fault has occurred within the plurality of terminals.

In this approach, the monitoring system is configured to, for each pairing of terminals, compare the measures of delay of the pairing of terminals together to predict whether or not a fault has occurred within the pairing of terminals. A pairing of terminals is a set of two terminals. Each pairing of terminals may have a different set of two terminals. For example, to supervise a set of 3 terminals, two or three pairs may be considered.

More particularly, in this approach, act 420 comprises iteratively performing an indicator generating process 505. The indicator generating process is configured to generate a respective predictive indicator for each pairing of terminals. Thus, if there are multiple pairings of terminals, a respective multiple number of predictive indicators is/are generated. A single predictive indicator could be subsequently generated responsive to the plurality of predictive indicators, e.g., if any predictive indicator indicates the predicted presence of a fault, then the single predictive indicator indicates the predicted presence of a fault.

The indicator generating process 505 comprises an act 510 of obtaining the pair of measures of delay for the pairing of terminals. These two measures of delay are then compared in an act 520. The predictive generator is produced, for the pairing of terminals, in an act 530 responsive to the outcome of the pairing.

The act 420 may further comprise a determination act 540 of determining whether there are any further pairings of terminals, whose pair of measures have not yet been processed. Responsive to a positive determination, act 420 may repeat the indicator generator process 505 for a next pairing of terminals. Otherwise, act 420 may end in an act 550.

Of course, rather than only one instance of the indicator generating process being performed at a time, the act 420 may comprise performing multiple instances in parallel, e.g., when the measures of delay become available. Thus, a pipeline and a parallel processing approach are considered.

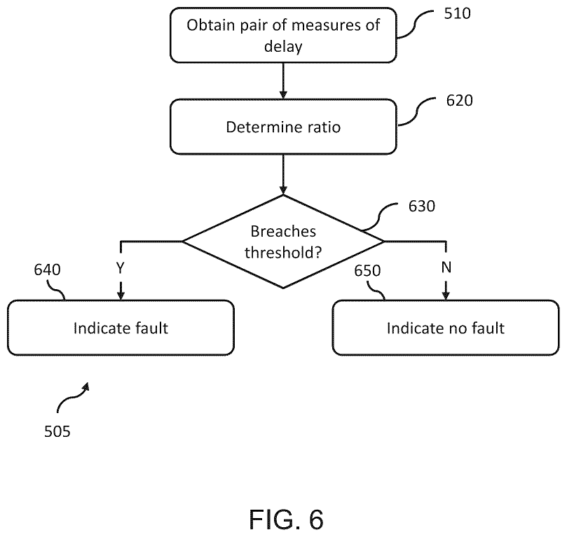

FIG. 6 illustrates one approach for performing the indicator generating process 605.

The process comprises the previously described act 610 of obtaining the pairs of measures of delay for the pairing of terminals. The process 605 further comprises determining 620 a ratio between the measures of delay. The ratio is then compared to a predetermined ratio threshold in act 630 to determine whether or not the ratio breaches the predetermined ratio threshold. Responsive to a positive determination in act 630 (i.e., the threshold is breached), act 610 comprises generating or defining the indicator for the pairing of terminals to indicate that there is a detected fault within the pairing of terminals. Responsive to a negative determination in act 630 (i.e., the threshold is breached), act 610 comprises generating or defining the indicator for the pairing of terminals to indicate that there is no detected fault within the pairing of terminals.

In a variation of the approach for performing the indicator generator process 605 illustrated by FIG. 6, act 620 comprises determining a difference between the measures of delay. The difference may then be compared to a predetermined threshold in act 630 to determine whether or not the difference breaches the predetermined threshold. The following acts may be otherwise identical, mutatis mutandis.

In previously described approaches, a parameter (e.g., a difference or ratio) derived from two measures of delay (and therefore pair of terminals) is compared to a threshold to predict whether or not a fault has occurred. The threshold may be predefined, e.g., a factory setting. Alternatively, the threshold may be defined using previously obtained measures of delay for the relevant pair of terminals, e.g., during a calibration procedure at well-defined operating conditions.

Thus, the monitoring system may be configured to perform a calibration procedure comprising: for each of a pair of terminals, obtaining a respective measure of delay for the signal provided to the respective terminal by the one or more signal generators; and processing the respective measures of delay to produce the threshold. The processing may be performed using the same technique as used to compare the two measures of delay (e.g., determining a difference or ratio, where appropriate).

In the previously disclosed approaches, a measure of delay is represented as being responsive to a single change of the generated signal (e.g., a single rise or fall of the generated signal). However, in some embodiments, the measure of delay is responsive to multiple changes of the generated signal, i.e., multiple time delays. To increase the probability of a good prediction result, filtering may be applied to each measure of delay before performing any comparison with other measures of delay. This technique reduces the risk of unintentionally attributing the occurrence of a fault short-term effects, e.g., due to noise. Filtering the outcome of any comparison (e.g., differences or ratios) may also be used for similar reasons.

As an example, a (combined) measure of delay (for a terminal) may be produced by summing, averaging or otherwise combining multiple measures of delay, generated using a previously described embodiment, for the terminal. The multiple measures of delay preferably represent the same type of delay, but for a different instance of a change in the generated signal. For example, a measure of delay may be generated for each of a plurality of pulses of the generated signal and combined. This (combined) measure of delay may then be processed or treated like any previously described measure of delay.

Put another way, a (combined) measure of delay for a terminal may be responsive to an accumulation (or combination) of two or more time delays, and preferably five or more time delays. Each time delay represents a time delay for a different instance of a change of the generated signal, which is preferably a same type of change for each of the two or more time delays (e.g., a rising edge delay, a falling edge delay or a (rising edge or falling edge) transition time). This approach is particularly advantageous for low-speed processing devices, as (in such devices) it is difficult to accurately measure the time delay for a single change of the generated signal.

In one approach for generated a (combined) measure of delay is for the monitoring system to be configured to perform a measure determination process for each terminal. The measure determination process may comprise combining or mixing the output signal (or the signal generated from the output signal) and the generated signal to produce a difference signal, e.g., using a digital XOR function. The difference signal may, for instance, be otherwise produced in an analog circuit, using a comparator or similar device, e.g., to comprise subtracting the output signal (or signal derived therefrom) from the difference signal. Deviations from zero in the difference signal indicate delays between the generated signal and the output signal (or signal derived therefrom). The resulting difference signal may be used as input for an analog integrator or filter.

The measure determination process may further comprise integrating the difference signal over a period of time. This effectively acts as a mechanism for combining multiple time delays together to produce a continuous monitor of the measure of delay.

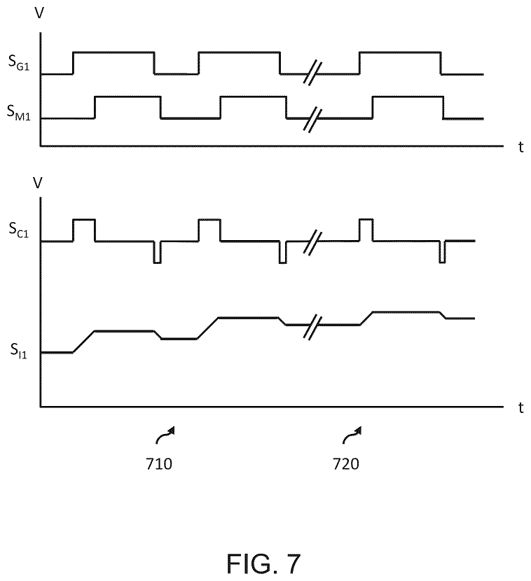

FIG. 7 illustrates the effect of a fault on a difference signal produced using the above-described approach.

In particular, FIG. 7 illustrates four waveforms, representing a generated signal S_{G1} for a terminal; a monitoring signal S_{M1} for the same terminal; a difference signal S_{D1} (produced by effectively subtracting the monitoring signal from the generated signal); and an integrated signal S_{I} produced by integrating the difference signal S_{D1}.

As illustrated in FIG. 7, the difference signal will effectively provide a digital representation of the round-trip delay. The integrated signal will represent a cumulative round-trip delay.

It will be appreciated that before a fault occurs at the terminal (e.g., during a pre-fault period 710), for each change of the generated signal (e.g., a length of time taken to go from a first low voltage to a first high voltage), then the integrated signal will change by a particular magnitude. However, after the fault occurs at the terminal (e.g., during a post-fault period 720), then the integrated signal will change by a different magnitude for a same change of the generated signal. Cumulatively over time, this results in the magnitude of the integrated signal changing differently during the post-fault period 720 than during the pre-fault period 710. In some embodiments the integrator or filter may be set to a known start condition before elaborating a new difference signal.

If an integrated signal is produced for each terminal, then a change in the monitored ratio or difference between two integrated signals of a pair of terminals can indicate the predicted occurrence of a fault within the pair of terminals.

The monitoring device may, for instance, comprise one or more analogue-to-digital converters (ADCs) for monitoring the integrated signal(s). In particular, the monitoring device may use the ADC(s) to produce a digital representation of the integrated signal.

In previously described approaches, the act of comparing measures of delay includes deriving a parameter (e.g., a difference or ratio) from two measures of delay (and therefore pair of terminals), and comparing this parameter to a threshold to predict whether or not a fault has occurred (within the pair of terminals).

However, another approach comprises monitoring a change in this derived parameter (e.g., difference or ratio) over time. Predicting whether or not a fault has occurred may comprise determining whether or not there is a significant change in this parameter within a predefined time window, which may be a moving time window. In this context, a significant change may comprise a change by more than a predetermined percentage, a gradient of more than a predetermined gradient, a range of more than a predetermined range and so on. Especially for monitoring of parameters over time, a higher number of measurement points from different pairings may be useful to be able to distinguish between effects due to potential failures and effects due to temperature variation or supply voltage variation.

Accordingly, in some examples, the monitoring system may be configured to for each of the plurality of terminals and each of a plurality of different time points, obtain a respective measure of delay for the signal provided to the respective terminal by the one or more signal generators. The monitoring system may be further configured to, for each of one or more different pairings of terminals: produce a measure of difference, for each of the plurality of different time points, between the measures of delay of the pairing of terminals at said time point; and monitor changes in the measures of delay, across the plurality of different time points, to predict whether or not a fault has occurred within the pairing of terminals.

In this way, a longitudinal analysis of the measures of delay may be employed.

In preferred examples, the plurality of terminals comprises at least three terminals. In such examples, the monitoring system may be configured to compare the measures of delay to one another by, for each of one or more different pairings of terminals, comparing the measures of delay of the pairing of terminals together to predict whether or not a fault has occurred within the pairing of terminals. Approaches for comparing measures of delay have been previously described.

In this approach, the one or more different pairings of terminals preferably defines each terminal as belonging to at least two different pairings of terminals. Thus, if the plurality of terminals comprises only three terminals, then each terminal may belong to two different pairings of terminals, for a total of three pairings of terminals.

This approach reduces a likelihood of a fault between two terminals (e.g., a shorting of two terminals) going undetected. In particular, as each terminal belongs to at least two different pairings of terminals, then it can be expected that a fault will be detected with respect to at least one of the pairings of terminals. This might otherwise go missed if two terminals belong to only a single, shared pairing of terminals (e.g., as the difference or ratio between the two measures of difference will remain substantially constant as the measures of delay are likely to be affected in a similar way). A careful selection of pairings may also be used to find out which terminal already shows a weakness or is degrading towards a failure case. This knowledge may be used by another instance on system level to change the usage of a terminal, especially if redundancy in terminals is possible.

The present disclosure provides a number of example types of measure of delay, including a rising edge delay, a falling edge delay, a rising edge transition time and falling edge transition time. Some further examples include measures of delay produced by combining a plurality of instances of one or more types of one or these measures of delay, e.g., combining a single type of one of these measures of delay.

In some examples, the monitoring system is configured to: for each of the plurality of terminals and each of two or more types of measure of delay, obtain a respective measure of delay for the signal provided to the respective terminal by the one or more signal generators. The monitoring system may be further configured to, for each type of measure of delay, compare the measures of delay (in the same type) to one another to generate an indicator of whether or not a fault has occurred within the plurality of terminals.

In this way, multiple types of measures of delay can be analyzed or processed to predict whether or not a fault has occurred.

The indicator produced using any above-described approach may be used, e.g., by the monitoring system, to control or trigger one or more further actions.

By way of example, the monitoring system may be configured to, responsive to the indicator indicating that a fault has occurred within the plurality of terminals, control a user-interface to provide a user-perceptible output of the occurrence of a fault. This may comprise, for instance, controlling a display or other visual output element (e.g., a light) to indicate that a fault has occurred or will occur (e.g., by activating, flashing a particular pattern, turning a particular color and so on). As another example, the monitoring interface may control an audible output element (e.g., a buzzer or speaker) to provide an audio output that a fault has occurred.

By way of another example, the monitoring system may be configured to generate and store data (e.g., in a database) that a predicted fault has occurred responsive to the indicator indicating that a fault has occurred or will occur within the plurality of terminals. This data can be subsequently used or referenced for performing further actions using the semiconductor arrangement.

In addition to the above-described examples, the following examples are disclosed.
Example 1. A semiconductor arrangement comprising:
a plurality of terminals;
one or more signal generators configured to provide a signal to each of the plurality of terminals; and
a monitoring system configured to:
for each of the plurality of terminals, obtain a respective measure of delay for the signal provided to the respective terminal by the one or more signal generators; and
compare the measures of delay to one another to generate an indicator of whether or not a fault has occurred within the plurality of terminals.
Example 2. The semiconductor arrangement of example 1, wherein the semiconductor arrangement further comprises, for each of the plurality of terminals:
an output driver connected between the one or more signal generators and the respective terminal, wherein the output driver is configured to generate and provide, to the respective terminal, an output signal responsive to a respective generated signal generated by the one or more signal generators;
wherein each measure of delay is responsive to at least one time delay between:
a change in the generated signal provided to the output driver connected to the respective terminal; and
a corresponding change in the output signal, or a signal generated from the output signal, read from the respective terminal, that is responsive to the change in the generated signal.
Example 3. The semiconductor arrangement of example 2, wherein the semiconductor arrangement further comprises, for each of the plurality of terminals:
an input driver connected to the respective terminal, wherein the input driver is configured to read a signal at the respective terminal to thereby generate a monitoring signal responsive to the output signal provided to the respective terminal by the output driver connected to the respective terminal;
   wherein each time delay is a time delay between:
a change in the generated signal provided to the output driver connected to the respective terminal; and
a corresponding change in the monitoring signal that is responsive to the change in the generated signal.
Example 4. The semiconductor arrangement of example 2 or 3, wherein the change in the generated signal is a rising edge of the generated signal and the corresponding change in the output signal, or the signal generated from the output signal, is a corresponding rising edge of the output signal or the signal generated from the output signal.
Example 5. The semiconductor arrangement of example 4, wherein each time delay represents a difference in time between:
a first point in time at which a voltage of the generated signal changes from a first low voltage to a first predetermined percentage of a first high voltage; and
a second point in time at which a voltage of the output signal, or the signal generated from the output signal, changes from a second low voltage to a second predetermined percentage of a second high voltage.
Example 6. The semiconductor arrangement of example 5, wherein the first point in time is detected using a first Schmitt trigger and the second point in time is detected using a second Schmitt trigger.
Example 7. The semiconductor arrangement of example 2 or 3, wherein the change in the generated signal is a falling edge of the generated signal and the corresponding change in the output signal, or the signal generated from the output signal, is a corresponding falling edge of the output signal or the signal generated from the output signal.
Example 8. The semiconductor arrangement of any of examples 2 to 7, wherein each measure of delay is responsive to an accumulation of two or more time delays.
Example 9. The semiconductor arrangement of any of examples 2 to 8, wherein the monitoring system is configured to obtain, for each of the plurality of terminals, the respective measure of delay by performing a measure determination process comprising combining the output signal, or the signal generated from the output signal, from the generated signal to produce a difference signal.
Example 10. The semiconductor arrangement of example 9, wherein the measure determination process further comprises integrating the difference signal over a period of time.
Example 11. The semiconductor arrangement of example 1, wherein each measure of delay is responsive to at least one transition time of a terminal signal read from the respective terminal, wherein each transition time is a length of time taken for a voltage of the terminal signal to rise from a first value to a second value or fall from a third value to a fourth value.
Example 12. The semiconductor arrangement of any of examples 1 to 11, wherein the monitoring system is configured to compare the measures of delay to one another by, for each of one or more different pairings of terminals, comparing the measures of delay of the pairing of terminals together to predict whether or not a fault has occurred within the pairing of terminals.
Example 13. The semiconductor arrangement of example 11, wherein the monitoring system is configured to, for each of one or more different pairings of terminals, compare the measures of delay of the pairing of terminals by:
determining a ratio of the measures of delay; and
processing the determined ratio to predict whether or not a fault has occurred within the pairing of terminals.
Example 14. The semiconductor arrangement of example 13, wherein the monitoring system is configured to, for each of one or more different pairings of terminals, process the determined ratio by comparing the ratio to a predetermined ratio threshold, for the pairing of terminals, to predict whether or not a fault has occurred within the pairing of terminals.
Example 15. The semiconductor arrangement of example 14, wherein each predetermined ratio threshold represents a ratio between previously obtained measures of delay for the pairing of terminals.
Example 16. The semiconductor arrangement of any of examples 1 to 15, wherein the monitoring system is configured to:
for each of the plurality of terminals and each of a plurality of different time points, obtain a respective measure of delay for the signal provided to the respective terminal by the one or more signal generators; and
for each of one or more different pairings of terminals:
for each of the plurality of different time points, produce a measure of difference between the measures of delay of the pairing of terminals; and
monitor changes in the measures of delay, across the plurality of different time points, to predict whether or not a fault has occurred within the pairing of terminals.
Example 17. The semiconductor arrangement of any of examples 1 to 16, wherein the plurality of terminals comprises at least three terminals.
Example 18. The semiconductor arrangement of any of examples 1 to 17, wherein the semiconductor arrangement is an integrated circuit.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

1. A semiconductor arrangement comprising:
a plurality of terminals;
one or more signal generator circuits configured to provide a signal to each of the plurality of terminals; and
a monitoring circuit configured to:
for each of the plurality of terminals, obtain a respective measure of delay for the signal provided to the respective terminal by the one or more signal generator circuits; and
compare the measures of delay to one another to generate an indicator of whether or not a fault has occurred within the plurality of terminals.

2. The semiconductor arrangement of claim 1, wherein the semiconductor arrangement further comprises, for each of the plurality of terminals:
an output driver connected between the one or more signal generators and the respective terminal, wherein the output driver is configured to generate and provide, to the respective terminal, an output signal responsive to a respective generated signal generated by the one or more signal generator circuits;
wherein each measure of delay is responsive to at least one time delay between:
a change in the generated signal provided to the output driver connected to the respective terminal; and
a corresponding change in the output signal, or a signal generated from the output signal, read from the respective terminal, that is responsive to the change in the generated signal.

3. The semiconductor arrangement of claim 2, wherein the semiconductor arrangement further comprises, for each of the plurality of terminals:
an input driver connected to the respective terminal, wherein the input driver is configured to read a signal at the respective terminal to thereby generate a monitoring signal responsive to the output signal provided to the respective terminal by the output driver connected to the respective terminal;
wherein each time delay is a time delay between:
a change in the generated signal provided to the output driver connected to the respective terminal; and
a corresponding change in the monitoring signal that is responsive to the change in the generated signal.

4. The semiconductor arrangement of claim 2, wherein the change in the generated signal is a rising edge of the generated signal and the corresponding change in the output signal, or the signal generated from the output signal, is a corresponding rising edge of the output signal or the signal generated from the output signal.

5. The semiconductor arrangement of claim 4, wherein each time delay represents a difference in time between:
a first point in time at which a voltage of the generated signal changes from a first low voltage to a first predetermined percentage of a first high voltage; and
a second point in time at which a voltage of the output signal, or the signal generated from the output signal, changes from a second low voltage to a second predetermined percentage of a second high voltage.

6. The semiconductor arrangement of claim 5, wherein the first point in time is detected using a first Schmitt trigger and the second point in time is detected using a second Schmitt trigger.

7. The semiconductor arrangement of claim 2, wherein the change in the generated signal is a falling edge of the generated signal and the corresponding change in the output signal, or the signal generated from the output signal, is a corresponding falling edge of the output signal or the signal generated from the output signal.

8. The semiconductor arrangement of claim 2, wherein each measure of delay is responsive to an accumulation of two or more time delays.

9. The semiconductor arrangement of claim 2, wherein the monitoring circuit is configured to obtain, for each of the plurality of terminals, the respective measure of delay by performing a measure determination process comprising combining the output signal, or the signal generated from the output signal, from the generated signal to produce a difference signal.

10. The semiconductor arrangement of claim 9, wherein the measure determination process further comprises integrating the difference signal over a period of time.

11. The semiconductor arrangement of claim 1, wherein each measure of delay is responsive to at least one transition time of a terminal signal read from the respective terminal, wherein each transition time is a length of time taken for a voltage of the terminal signal to rise from a first value to a second value or fall from a third value to a fourth value.

12. The semiconductor arrangement of claim 1, wherein the monitoring circuit is configured to compare the measures of delay to one another by, for each of one or more different pairings of terminals, comparing the measures of delay of the pairing of terminals together to predict whether or not a fault has occurred within the pairing of terminals.

13. The semiconductor arrangement of claim 11, wherein the monitoring circuit is configured to, for each of one or more different pairings of terminals, compare the measures of delay of the pairing of terminals by:
determining a ratio of the measures of delay; and
processing the determined ratio to predict whether or not a fault has occurred within the pairing of terminals.

14. The semiconductor arrangement of claim 13, wherein the monitoring circuit is configured to, for each of one or more different pairings of terminals, process the determined ratio by comparing the ratio to a predetermined ratio threshold, for the pairing of terminals, to predict whether or not a fault has occurred within the pairing of terminals.

15. The semiconductor arrangement of claim 14, wherein each predetermined ratio threshold represents a ratio between previously obtained measures of delay for the pairing of terminals.

16. The semiconductor arrangement of claim 1, wherein the monitoring circuit is configured to:
for each of the plurality of terminals and each of a plurality of different time points, obtain a respective measure of delay for the signal provided to the respective terminal by the one or more signal generator circuits; and
for each of one or more different pairings of terminals:
for each of the plurality of different time points, produce a measure of difference between the measures of delay of the pairing of terminals; and
monitor changes in the measures of delay, across the plurality of different time points, to predict whether or not a fault has occurred within the pairing of terminals.

17. The semiconductor arrangement of claim 1, wherein the plurality of terminals comprises at least three terminals.

18. The semiconductor arrangement of claim 1, wherein the semiconductor arrangement is an integrated circuit.

19. An integrated circuit, comprising:
a silicon substrate;
a signal generator circuit disposed on the silicon substrate;
a first output driver circuit disposed on the silicon substrate and having an input and an output, the input of the first output driver circuit coupled to the signal generator circuit;
a first pin coupled to the output of the first output driver circuit;
a first input driver circuit disposed on the silicon substrate and having an input and an output, the input of the first input driver circuit coupled to the first pin;
a second output driver circuit disposed on the silicon substrate and having an input and an output, the input of the second output driver circuit coupled to the signal generator circuit;
a second pin coupled to the output of the second output driver circuit;
a second input driver circuit disposed on the silicon substrate and having an input and an output, the input of the second input driver circuit coupled to the second pin; and
a monitoring circuit coupled to the output of the first input driver circuit and coupled to the output of the second input driver circuit, the monitoring circuit configured to: obtain a first measure of delay for a first signal provided to the first pin by the signal generator circuit and obtain a second measure of delay for a second signal provided to the second pin by the signal generator circuit, and provide a comparison of the first measure of delay to the second measure of delay and indicate that a fault has occurred based on the comparison.
